(19) United States
(12) Patent Application Publication
(10) Pub. No.: US 2008/0079150 A1
(43) Pub. Date: Apr. 3, 2008

(54) Die arrangement and method for producing a die arrangement

(76) Inventors: Juergen Simon, Dresden (DE); Laurence Edward Singleton, Dresden (DE); Jochen Thomas, Muenchen (DE)

Correspondence Address: SLATER & MATSIL LLP, 17950 PRESTON ROAD, SUITE 1000, DALLAS, TX, 75252, US

(21) Appl. No.: 11/529,779

(22) Filed: Sep. 28, 2006

(51) Int. Cl. H01L 23/48

(52) U.S. Cl. 257/737

(57) ABSTRACT

Die arrangement, having a die with a plurality of electronic circuits electrically coupled to one another, at least one first electrical connection region, having at least one electrical connection, and a first passivation layer, which is applied whilst leaving free at least the one first electrical connection region. A second passivation layer, preferably a molding material, is arranged at least partly on the first passivation layer. At least one electrically conductive structure with a connecting element and a redistribution layer electrically connects the first electrical connection to a second electrical connection, which is formed by or at a section of the redistribution layer. The connecting element extends from the first electrical connection region through the first passivation layer and the second passivation layer, the redistribution layer coupled to the connecting section being arranged at least partly on the second passivation layer.

### TECHNICAL FIELD

The invention relates to a die arrangement and a method for producing a die arrangement.

### BACKGROUND

In the context of packaging electronic chips, also referred to hereinafter as dies, it may be necessary to provide a redistribution wiring from first connection regions of a die, which are arranged for example in an inner region of the die, to second connection regions of the die, which may lie for example in an edge region of the die. This may be desirable if, for example, a connecting technique, for example wire bonding, is geared to forming the bonding wires in the edge regions of the dies. The redistribution wiring is affected for example, by means of additional electrical conductor tracks arranged in a so-called redistribution layer (RDL).

In redistribution layer technology, a metallic layer is deposited onto a dielectric, such as a polyimide or wafer level dielectric for example, arranged on a die or wafer. The thickness and the dielectric constant of said dielectric are crucial for the coupling capacitance with respect to the underlying metal layers of the silicon chip. This leads to an increase in the parasitic capacitance of the package and thus to limitation of the operating frequencies on account of the increased capacitive load. The redistribution layer may also couple interference into underlying conductor tracks and thus influence the functionality of the die.

Conventional redistribution layer technology attempts to reduce this coupling and parasitic capacitances by the arrangement of an additional dielectric (WPR) or a low-k dielectric.

However, with the present-day means for depositing dielectrics it is not possible to achieve sufficiently stable, reproducible and cost-effective layer thicknesses of greater than 15 μm dielectric thickness. Since spin-on dielectrics are typically used for the production of a redistribution layer, the layer thickness is limited in the case of these dielectrics since, in the course of crosslinking, volume shrinkage of up to 50% may occur, as for example in the case of a dielectric made of polyimide, with the result that an internal tensile stress arises which may lead to an undesirable flexure of the wafer or the singulated dies.

Although the shrinkage is reduced with the use of BCB (benzocyclobutene), in return BCB tends toward cracking at layer thicknesses of >5 μm-10 μm. High cure temperatures of these materials may lead to a retention yield loss.

For these and other reasons there is a need for the present invention as set out below on the basis of the embodiments.

### SUMMARY OF THE INVENTION

One embodiment of the invention provides a die arrangement. The die arrangement has a die, a multiplicity of electronic circuits that are electrically coupled to one another, at least one first electrical connection region, in which at least one electrical connection is arranged, and a first passivation layer, which is applied whilst leaving free at least the one first electrical connection region on the upper surface of the die. Furthermore, the die arrangement has a second passivation layer, which has a molding material and which is arranged at least partly on the first passivation layer. Furthermore, the die arrangement has at least one electrically conductive structure with a connecting element and a redistribution layer for electrically connecting the first electrical connection region to a second electrical connection region, which is formed by or at a section of the redistribution layer. The connecting element extends from the first electrical connection region through the first passivation layer and the second passivation layer, and the redistribution layer coupled to the connecting section is arranged at least partly on the second passivation layer.

In accordance with a further exemplary embodiment, the invention has a method for producing a die arrangement. The method has the formation of at least one connecting element on a first electrical connection of at least one first electrical connection region of a die with a multiplicity of electronic circuits that are electrically coupled to one another, at least one first electrical connection region, in which at least one first electrical connection is arranged, and a first passivation layer, which is applied on the upper surface of the die and which leaves free at least the first connection, in such a way that the connecting element extends approximately vertically from the electrical connection. Furthermore, the method has the formation of a second passivation layer made of a molding material on the first passivation layer whilst molding in the at least one connecting element, the formation of at least one redistribution layer on the surface of the second passivation layer whilst producing an electrical connection to the free end of the at least one connecting element, and the formation of at least one second electrical connection region with a second electrical connection at the redistribution layer by arranging a covering layer on the top side of the second passivation layer whilst leaving free at least one section at the at least one redistribution layer.

These and further features of the invention will become clearer from the following description with reference to the accompanying Figures.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a sectional view of a die arrangement in accordance with one embodiment of the invention;

FIG. 2 shows a connecting element of an electrically conductive structure in accordance with one embodiment of the invention;

FIGS. 3A to 3I show individual processes for producing a die arrangement in accordance with one embodiment of the invention;

FIG. 4 shows a die arrangement with an at least partly formed second passivation layer;

FIG. 5 shows a die arrangement with a bonding pad for parameter tests; and

FIG. 6 shows a flowchart illustrating a method for producing a die arrangement in accordance with one exemplary embodiment of the invention.

### DETAILED DESCRIPTION OF ILLUSTRATIVE EMBODIMENTS

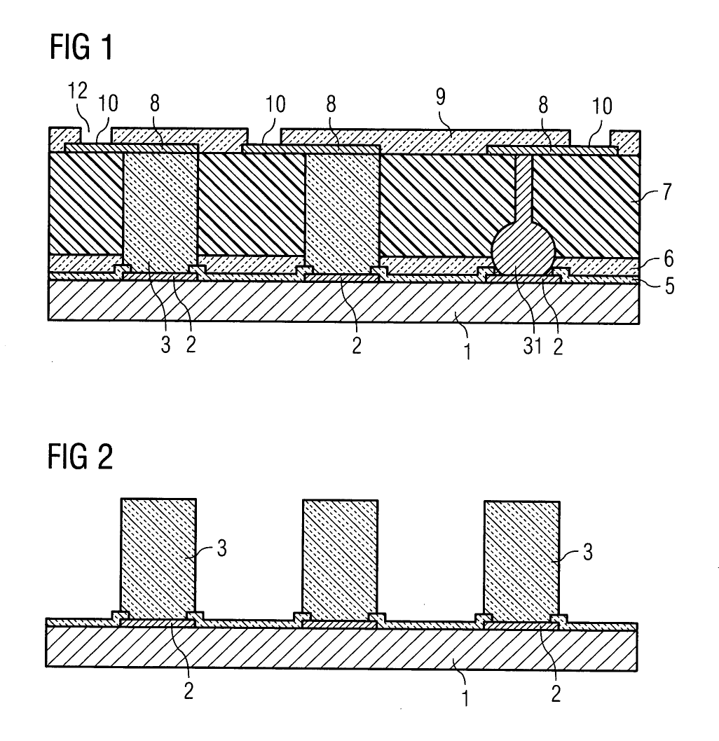

FIG. 1 illustrates a sectional view of a die arrangement in accordance with one embodiment of the invention.

As is illustrated in FIG. 1, the die arrangement has a die 1 with a multiplicity of electronic circuits (not shown) that are electrically coupled to one another. A first passivation layer 5 (hard passivation), which is customary per se in the case of die 1 and which may be produced from polyimide for example, is arranged on the surface of the die 1. Furthermore, a multiplicity of first electrical connection regions, each having at least one electrical connection, are arranged on the surface of the die 1, which are referred to hereinafter as bonding pads 2, only three bonding pads 2 being schematically illustrated by way of example in FIG. 1. The first passivation layer 5 is omitted in the regions of the bonding pads 2.

A third passivation layer 6, which may be used for example in die arrangements for DRAM products, is optionally arranged on the first passivation layer 5, likewise whilst leaving free the bonding pads 2. Said third passivation layer 6, which for example has a layer thickness of approximately 5 μm and may be produced form a polyimide, may serve as an additional stress buffer.

Arranged on the bonding pads 2 is in each case a connecting element 3, 31, which are in each case associated with an electrically conductive structure arranged for enabling a redistribution wiring at the die.

FIG. 1 schematically illustrates two differently produced connecting elements 3, 31, as examples of such a connecting element 3, 31, although only one of the different types of connecting elements 3, 31 is used uniformly in the completion of a die 1. The differently produced connecting elements 3, 31 fulfill the same purpose in the die arrangement in accordance with FIG. 1, and so the type of connecting element 3, 31 will not be discussed in any greater detail at this juncture. By way of example, the connecting elements 3, 31 may be applied to the bonding pads 2 of a die 1 at the wafer level.

As can furthermore be seen from FIG. 1, a second passivation layer 7 is arranged at least partly on the optional third passivation layer 6 (or on the first passivation layer 5 if the third passivation layer 6 is not provided), which second passivation layer 7 has a molding material and encapsulates the connecting elements 3, 31 essentially so completely that only the upper ends of the connecting elements 3, 31 are free of molding material. The second passivation layer 7, which in this embodiment, is referred to hereinafter as molding layer 7, may be applied to the die 1 of the die arrangement in a molding method, by way of example. The upper end face of the connecting elements 3, 31 can be kept free for example by means of exposed molding. As an alternative to this, the molding layer 7 may also be applied in a printing method, such as a vacuum printing encapsulation process (VPES) for example.

As can furthermore be seen from FIG. 1, a corresponding number of redistribution layers 8 respectively assigned to a bonding pad 2 are arranged on the top side of the molding layer 7, which redistribution layers are in each case electrically conductively connected to an assigned connecting element 3, 31 and extend along the top side of the molding layer 7. As already mentioned above, the die arrangement in accordance with FIG. 1 may be a die assemblage or a wafer, which is subdivided into individual dies after completion of the redistribution wiring. The orientation and length of the redistribution layers 8 is accordingly effected in accordance with a predetermined scheme in such a way that the redistribution layers 8 extend for example toward edge regions (not illustrated) of the dies that are subsequently to be singulated, and may thus provide sections for new connection regions at the corresponding edge regions. Corresponding alignment markings may be used for the processing of the redistribution layers 8.

As can furthermore be seen from FIG. 1, a second electrical connection region with at least one electrical connection, referred to henceforth as second bonding pad 10, is in each case formed at or by a section of the redistribution layers 8. The new or second bonding pads 10 are provided by or at the top side of the respective redistribution layers 8, the corresponding bonding pad area being delimited by a covering layer 9 arranged at least partly on the top side of the molding layer 7 in a manner at least partly covering the redistribution layers 8. The second bonding pad 10 provided by means of the opening or cutout 12 in the covering layer 9 at the redistribution layers 8 may be formed according to the further envisaged use of the die arrangement, that is to say that the bonding pad area for the use of the die arrangement as wafer level chip size packages (CSP), in which solder balls are arranged at the bonding pads 10, may be made larger than the bonding pad area when the die arrangement is used for wire bonded MCPs.

The covering layer 9 may be formed as a protective layer or else as a soldering resist for the use as wafer level chip size packages (CSP). The covering layer 9 may be applied for example, by screen printing or some other suitable application method.

Since the molding layer 7 is applied to the first passivation layer 5, or alternatively to the third passivation layer 6 provided that such a third passivation layer is provided, for example by means of a molding method or a printing method, the molding layer 7 can be produced with a thickness of >30 μm. On account of the molding material used, which may have for example an epoxy resin mixed with corresponding fillers, what may be achieved, even in the case where the molding layer has a layer thickness of approximately 50 μm, is that no or an only very negligible shrinkage of the molding material takes place during the curing of the molding material, with the result that flexure of the die is avoided. Since, furthermore, the curing temperature of the molding material after molding or printing is a maximum of 180° C., this has the effect that the retention yield loss is lower than when using a polyimide which is applied by means of a spin-on process in accordance with the conventional production of a passivation layer.

Since, in accordance with one embodiment of the invention, as already specified, the second passivation layer 7, sometimes referred to herein as the molding layer 7, can be formed with a thickness of greater than 30 μm between the first passivation layer 5 and the redistribution layers 8 arranged on the top side of the molding layer 7. Thus, it is advantageously achieved that the parasitic capacitances can be decisively reduced, so that the die arrangement consequently enables a significant improvement of the electrical performance at high clock frequencies, in conjunction with better signal transmission. A further advantage of the die arrangement in accordance with one embodiment of the invention is that the second passivation layer 7, in which the connecting elements 3, 31 are essentially encapsulated and by means of which the increased distance between the active die surface and the redistribution layer 8 is provided, can be produced by molding or printing. Consequently, for the production of said second passivation layer 7, it is not necessary to provide a material which has to be photopatternable. The molding material used for producing the second passivation layer 7 not only has more favorable processing properties but can also be provided at lower cost.

Yet another advantage of the molding or printing of the second passivation layer 7 and of the molding material which is to be used for this purpose and which does not have to be photopatternable furthermore consists in the fact that additional fillers may be admixed with the molding material, which may have an epoxy resin for example, by means of which fillers the coefficient of thermal expansion (CTE) of the molding material and/or the dielectric constant of the molding material can be influenced in a targeted manner in a desired way. A suitable filler with regard to influencing the coefficient of thermal expansion may be a silicon dioxide (spherical filler amorphous), for example.

Furthermore, it is possible to admix with the epoxy resin further or other fillers, which may for example influence the shrinkage behavior during curing, the thermal conductivity of the molding material and also, for example, specific mechanical properties, so that for forming the second passivation layer 7 it is possible to provide a molding material which has a desired or required castability and also desired or required mechanical, thermal and electrical properties and can form a composite structure with the first passivation layer 5 or with the second passivation layer 6, if present, and with the connecting elements 3, 31.

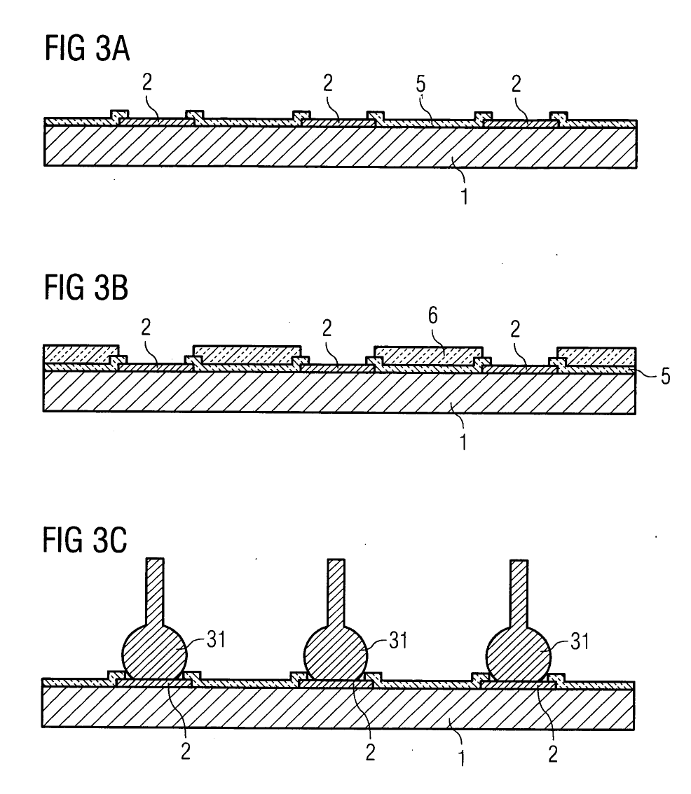

FIG. 2 shows a connecting element of an electrically conductive structure in accordance with one embodiment of the invention.

The connecting element 3, shown in FIG. 2, a multiplicity of connecting elements 3 (only three connecting elements 3 are illustrated by way of example in FIG. 2) may be used for example as a connecting element of an electrically conductive structure of a die arrangement described in FIG. 1. The pillar-type connecting element 3 (referred to hereinafter as bump 3), which is electrically conductively connected directly to the bonding pad 2 of the die 1, is for example, an electrodeposited bump formed prior to the arrangement of the molding layer 7 (see FIG. 1).

Prior to the production or the deposition of the bumps 3, usually after the processing of a start layer (seed layer) and the formation of a corresponding structure made of photoresist, an under bump metallization (UBM) is applied to the die 1 directly onto the opened bonding pad structure. This is followed by the electrodeposition of the bumps 3, which may have copper, for example, it being possible for the bumps 3 to be formed in pillar-type fashion on account of the structure made of photoresist. After the subsequent removal of the photoresist and the start layer, the die 1 may then be provided with the molding layer 7 (FIG. 1) by encapsulating or embedding the connecting elements 3 in the molding material of the molding layer 7.

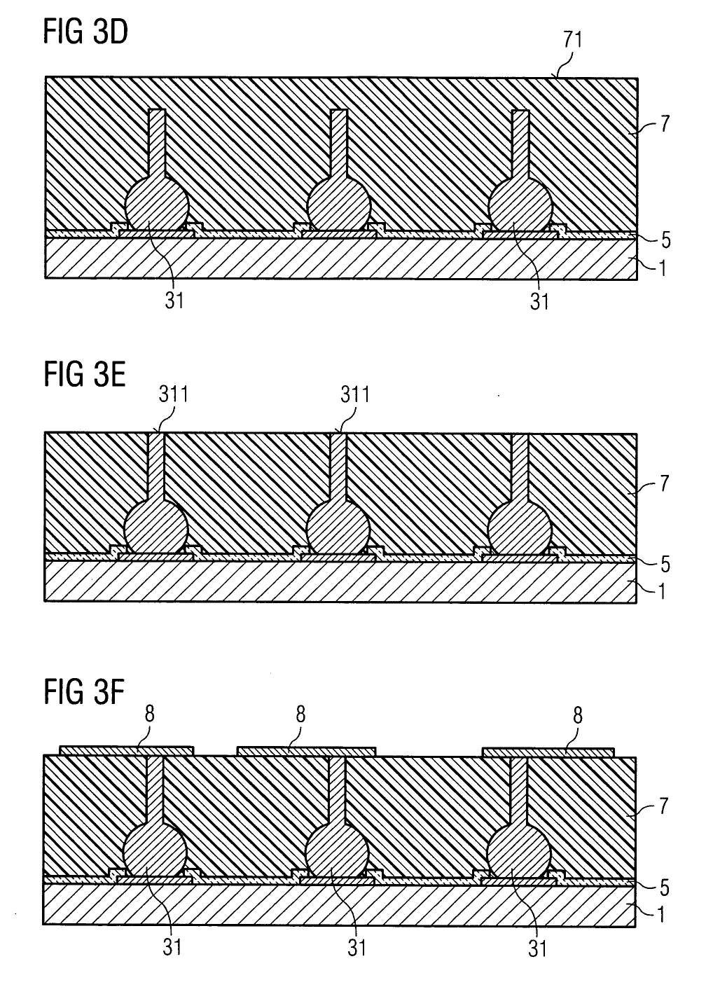

Instead of the electrodeposited connecting elements 3 described with reference to FIG. 2, however, different connecting elements may also be arranged on the bonding pads 2. One example of a different connecting element 31, which is schematically illustrated for example in FIGS. 1 and 3, is a so-called stud bump 31, which can be applied to the bonding pad 2 mechanically in a maskless method step. Furthermore, arranging the stud bumps 31 on the bonding pads 2 does not require an electroplating start layer (also referred to as seed layer), that is to say a UBM, so that, depending on the number of stud bumps 31, such as for example in the case of relatively large dies with a small number of connections, it is possible to achieve a cost reduction in the production of the die arrangement. It is furthermore possible to arrange a plurality of stud bumps 31 (stacked) one above another, so that a stud bump 31 having a required/desired height can be provided in a simple manner. The material of the stud bumps 31 has gold or copper, for example.

FIGS. 3A to 3I schematically show individual method processes for producing a die arrangement in accordance with one embodiment of the invention, on the basis of which the method in accordance with one embodiment is explained in more detail below.

FIG. 3A illustrates a die 1, which has a multiplicity of electronic circuits (not shown) that are electrically coupled to one another, and which is suitable for producing a die arrangement in accordance with one embodiment of the invention.

As can be seen from FIG. 3A, a customary first passivation layer 5 (hard passivation) is arranged on the surface of the finished processed die 1 and is provided with cutouts which uncover a multiplicity of bonding pads 2, although only three bonding pads 2 are shown in each case by way of example in the illustration in accordance with FIGS. 2A to 2I, said bonding pads corresponding to the first electrical connection regions with, in each case, at least one electrical connection.

As illustrated in FIG. 3B, in a first step the die 1 is provided with a third passivation layer 6, which is applied to the first passivation layer 5 whilst exposing or leaving free the first electrical connection regions, that is to say the first bonding pads 2, and serves for example as a stress buffer. However, the arrangement of this third passivation layer 6, which may have a polyimide for example, is optional and not necessary for all types of use of die arrangements. An exemplary application of a die arrangement having such a third passivation layer 6 serving as a stress buffer may be a DRAM.

Since such a third passivation layer 6 is not absolutely necessary for the die arrangement in accordance with one embodiment of the invention, the illustration of said third passivation layer 6 is dispensed with in the subsequent Figures and the associated description.

The next method process in the production of the die arrangement in accordance with one embodiment of the invention involves effecting, as is illustrated in FIG. 3C, the arrangement of the connecting elements 3, 31, which in this exemplary embodiment are embodied in the form of stud bumps 31. In this case, the stud bumps 31 are arranged mechanically on the bonding pads 2 for example, of the entire die arrangement, for example at the wafer level, it being possible for the desired or required height of the stud bumps 31 to be correspondingly established by arranging or stacking a plurality of stud bumps one above another. For realizing the connection of the stud bumps 31 on the bonding pads 2 by means of a stud bumping process, it is not necessary to provide the bonding pads 2 with a galvanic start layer.

As can be seen from FIG. 3D, the die 1 completed with the stud bumps 31, for example, is subsequently provided with the second passivation layer 7, also referred to as molding layer 7 hereinafter. The formation of said molding layer 7 may be effected for example by means of a molding process or a stencil printing process, such as a vacuum printing encapsulating process, for example. The formation of said molding layer 7 with a material having an epoxy resin for example, and using one of the processes described has the advantage that any desired or required layer thickness can be produced, the stud bumps 31 either being able to be completely molded in or, as shown in FIG. 3E, being embedded in the molding material by means of exposed molding such that the upper end sections of the stud bumps 31 remain free of molding material.

For the case where the stud bumps 31 on the die 1 are completely embedded in the molding layer 7 during the molding or printing operation, as is shown in FIG. 3D, a next process involves effecting removal, such as, for example, in the form of grinding away, a material layer at the top side 71 of the molding layer 7 until the molding layer 7 has a predetermined thickness, such as 50 μm, for example, and an upper section 311 of the stud bumps 31 is uncovered, as illustrated in FIG. 3E.

In a next method process, as illustrated in FIG. 3F, the redistribution layers (RDL) 8 are arranged on the top side of the molding layer 7, a redistribution layer 8 being assigned to each of the stud bumps 31 and being electrically conductively connected thereto, the intention being to provide by means of the redistribution layers 8 respective new or second bonding pads 10 (in FIG. 1) which are arranged at a different position relative to the respectively assigned original bonding pad 2 on the die 1.

Since the stud bumps 31 or the electrodeposited bumps 3 which are embedded in the molding layer 7 then have copper or gold rather than aluminum, like the original bonding pads 2, it is possible, in order to achieve sufficiently good adhesion properties of the redistribution layers 8 with the stud bumps 31 or bumps 3, prior to the processing of the redistribution layers 8, optionally to use a chemical metallization instead of applying an electroplating start layer, which requires an upstream thin-film process. Afterward, the redistribution layers 8 may essentially be effected by means of a customary electrodeposition process using a previously formed mask, firstly the redistribution layers 8, which have copper, and onto these a covering layer being processed, which, depending on the further purpose of use of the die arrangement, for example for wire bonding or solder bonding, may have for example nickel (Ni) or gold (Au) or an alloy thereof and ensures the solderability of the redistribution layers 8.

Since, in accordance with an embodiment of the invention, the passivation layer arranged between the active surface of the die 1 and the redistribution layers 8 is a molding layer 7 having molding material, such a layer may be formed with a thickness of 50 μm, for example, with the result that parasitic capacitances between the active surface of the die 1 and the redistribution layers 8 can be excluded or prevented to the greatest possible extent even at high operating frequencies. Consequently, the electrical performance of the die arrangement according to an embodiment of the invention is significantly improved compared with conventional die arrangements. Moreover, the molding material may have added to it additives that can influence for example the dielectric constant of said molding material in a desired manner, so that the molding layer 7 may have the improved properties not only by way of its thickness but also on account of its material. It is possible to admix additives or fillers with the molding material because, as already mentioned, the molding layer 7 can be applied to the die 1 in a molding process or a printing process and, consequently, does not need to have photopatternable properties. A further advantage of forming the second passivation layer from molding material is that the retention yield loss is reduced at molding temperatures of typically 180° C.

As can be seen from FIG. 3G, by means of a further production step, which is not mandatory, however, with regard to the invention, a covering layer 9 is finally applied to the top side of the molding layer 7 at least partly and whilst at least partly covering the redistribution layers 8 such that the respective second electrical connection region 10 of the die 1, that is to say the second bonding pad 10, is provided at each of the corresponding redistribution layers 8 with the covering layer 9 respectively being cut out. The cutout 12 in the covering layer 9, which is applied to the die arrangement by means of a stencil printing process, for example, circumscribes on the redistribution layers 8 a region by which or in which the bonding pad 10 is formed, so that the circumferential sections of the cutout 12 that delimit the cutout 12 of the covering layer 9 simultaneously act as a solder stop for example for a later use of the die arrangement as wafer level CSP. By multiple repetition of this process, it is possible for example to produce a multilayer wiring. The covering layer 9 may have for example polyimide or a solder mask material.

An alternative configuration of the covering layer 9 is shown in FIG. 3H, this configuration of the die arrangement being formed in a suitable manner for later wire bonding, for example, in which the distances between the bonding pads 101 and also the size of the cutouts 12 which surround the bonding pads 101 should in each case be smaller compared with those for solder bonding. The arrow 102 furthermore indicates that the bonding pad assigned to the redistribution layer 81 is formed in the region of a different edge of the die arrangement and is concealed in the sectional plane illustrated in FIG. 3H. The embodiment of the die arrangement as shown in FIG. 3H may be used for example for a stacked die arrangement for or in a wire bonded multichip package (MCPs).

Although not illustrated separately, in the production phase for the die arrangement shown in FIG. 3H the thickness of the die 1 may optionally be reduced for example by processing the inactive rear side 11 of the die 1 by means of a conventional removal method, such as grinding, for example.

Subsequently, including the optional reduction of the thickness of the die 1, it is possible, as can be seen from FIG. 3I, for the bonding pads 10 of the die arrangement in accordance with FIG. 3G to be provided with solder balls 20 by means of a further method process, which is not mandatory, however, with regard to the invention. A die which is suitable for the use of a wafer level chip size package (CSP) is now provided with the die arrangement in accordance with FIG. 3I.

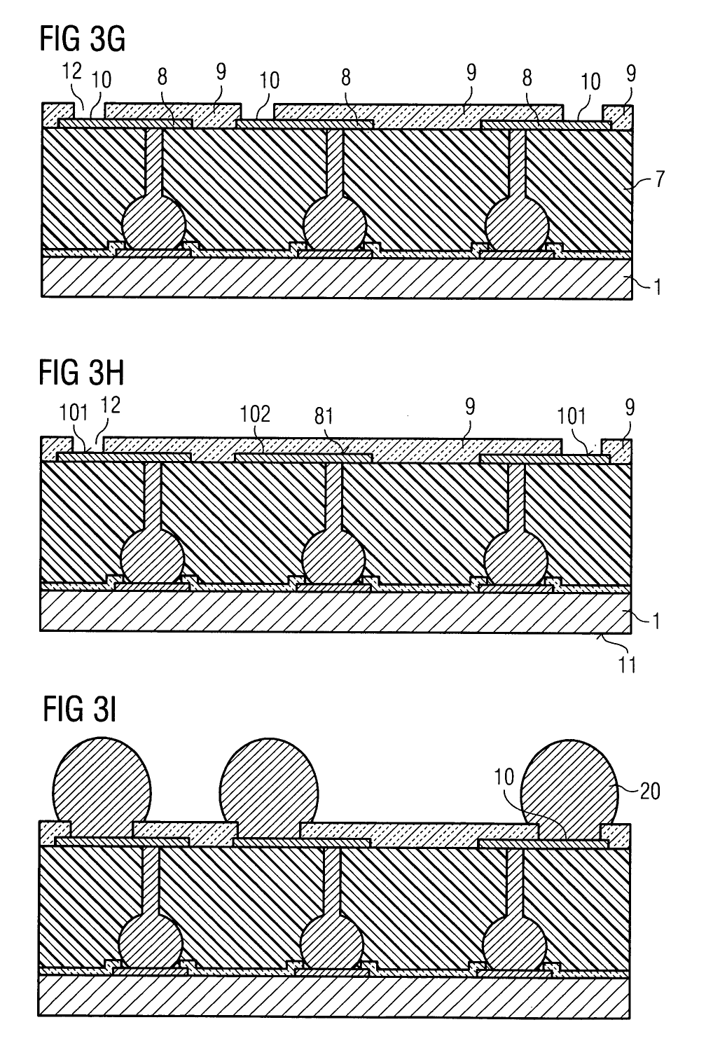

As can be seen from FIG. 4, the molding layer 7 of a die arrangement in accordance with one embodiment of the invention, in contrast to the illustrations in FIGS. 3D and 3E, for example, may, during molding, also be arranged only in sections on the first passivation layer 5 or, if present, on the third passivation layer 6. Both the material used for the molding layer 7 and the processes used for the arrangement of the molding layer 7, such as a molding process or a printing process, for example, are suitable for the formation of a molding layer which does not extend completely over the entire area of the die 1, but rather is formed only partly on the die 1, but the connecting elements 3, 31 are in each case embedded in the partly arranged molding layer 7. Such sections free of molding layer 7 of the die 1 may be formed for example in each case at regions 103 along which the die arrangement can be singulated into a multiplicity of die arrangements in a possibly subsequent dicing process, for example by means of a sawing operation. That is to say that the sections free of molding layer 7 can be aligned for example in accordance with a dicing structure and be formed in each case for example along dicing channels between the die arrangements to be singulated.

Said sections free of molding layer 7 may furthermore be utilized, for example, as alignment markings for the processing of the redistribution layers 8 that are affected after the molding of the second passivation layer (molding layer 7).

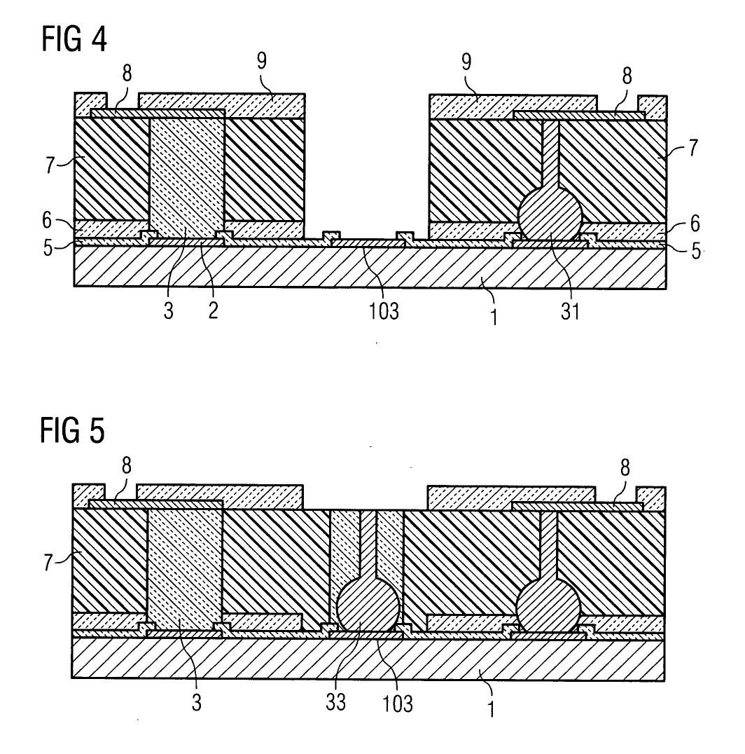

Another possibility for the alignment of the redistribution layers 8 that are to be arranged after the molding of the second passivation layer (molding layer 7) is illustrated in FIG. 5 and may consist for example in utilizing bonding pads 103 formed at the die 1 as reference marking, which bonding pads are formed for carrying out parameter tests at the die 1. The bonding pads 103 for parameter tests have a connecting element 33 which extends through the molding layer 7 and which may be used as alignment marking for the processing of the redistribution layers 8, but the connecting element 33 is not used for connection to the redistribution layers 8. Rather, connecting elements 33 of this type are, in each case, arranged in regions of dicing channels.

The die arrangement produced, for example, at the wafer level in accordance with one embodiment of the invention may, as already mentioned, be singulated into individual completed dies after, for example, the arrangement of the solder balls 20 (FIG. 3I), it being possible for the die arrangement to be aligned for the, for example, sawing process, for example, on the basis of the dicing channels not covered with molding material (FIG. 4) or by means of the bonding pads 103 and connecting elements 33 (FIG. 5), which are formed for parameter tests at the die 1 and which are arranged in the region of the dicing channels.

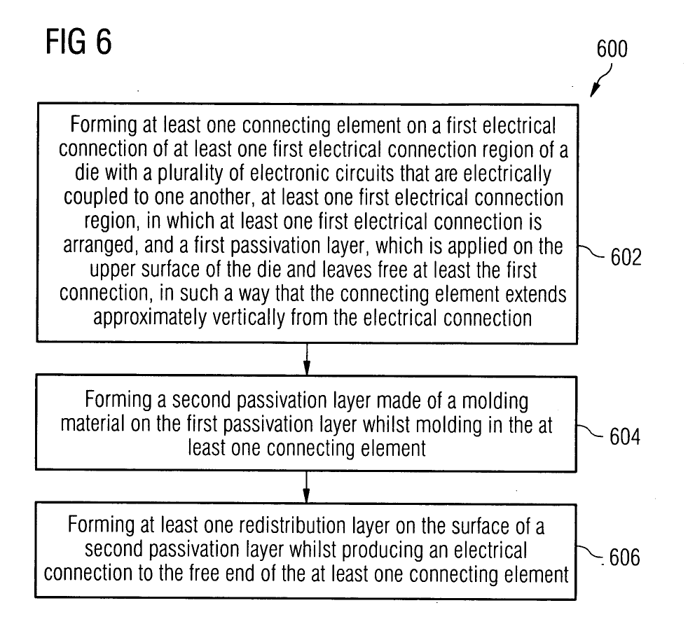

FIG. 6 shows a flowchart 600 illustrating a method for producing a die arrangement in accordance with one exemplary embodiment of the invention.

602 involves effecting formation of at least one connecting element on a first electrical connection of at least one first electrical connection region of a die with a multiplicity of electronic circuits that are electrically coupled to one another, at least one first electrical connection region, in which at least one first electrical connection is arranged, and a first passivation layer, which is applied on the upper surface of the die and leaves free at least the first connection, in such a way that the connecting element extends approximately vertically from the electrical connection.

604 involves effecting formation of a second passivation layer made of a molding material on the first passivation layer whilst molding in the at least one connecting element.

606 involves effecting formation of at least one redistribution layer on the surface of the second passivation layer whilst producing an electrical connection to the free end of the at least one connecting element.

The die arrangement in accordance with one embodiment of the invention has a die with a multiplicity of electronic circuits that are electrically coupled to one another, at least one first electrical connection region, in which at least one electrical connection is arranged, and a first passivation layer, which is applied whilst leaving free at least the one first electrical connection region on the upper surface of the die. A second passivation layer, which has a molding material, is arranged at least partly on the first passivation layer. Furthermore, the die arrangement has at least one electrically conductive structure with a connecting element and a redistribution layer for electrically connecting the first electrical connection region to a second electrical connection region, which is formed by or at a section of the redistribution layer, the connecting element extending from the first electrical connection region through the first passivation layer and the second passivation layer and the redistribution layer coupled to the connecting section being arranged at least partly on the second passivation layer.

The second passivation layer of the die arrangement may be produced by means of a molding method.

As an alternative, the second passivation layer may be produced by means of a printing process, such as a vacuum printing encapsulating process, for example.

The die arrangement is distinguished by the fact that the redistribution layer is arranged on the second passivation layer having a molding material.

Since the second passivation layer having a molding material can be produced by means of a molding process or a printing process, the molding layer can be provided with a correspondingly larger layer thickness, thereby achieving a reduction of parasitic capacitances in the high performance range. Since the second passivation layer can be produced by means of a molding process or a printing process, and the molding material is typically cured at lower temperatures than a passivation layer made of a conventional dielectric applied in a spin-on process, retention losses can be reduced or even avoided. Furthermore, on account of the material of the second passivation layer, despite a larger layer thickness, the die flexure can be reduced since the molding material has little shrinkage.

The die arrangement in accordance with one of the embodiments of the invention may be used, for example, for products or technologies regarding dual die package (DDP), wafer-level-package on board (WLPoB), flip-chip-in-package (FCiP), thru-silicon-via (TSV) and 3D integration.

The second passivation layer of the die arrangement may have a thickness of approximately 10 μm to 100μm.

The second passivation layer of the die arrangement has a thickness of approximately 50 μm.

The die arrangement may have a third passivation layer between the first passivation layer and the second passivation layer.

The third passivation layer may have polyimide.

The third passivation layer may have a thickness of approximately 1 μm to 10 μm.

The molding material of the second passivation layer of the die arrangement may have an epoxy resin.

Furthermore, the molding material may contain fillers that influence the coefficient of thermal expansion (CTE) of the molding material.

Furthermore, the molding material may contain fillers that influence the dielectric constant of the molding material.

The molding material has a curing temperature of less than or equal to approximately 180° C.

The connecting element of the electrically conductive structure of the die arrangement may be an electrodeposited bump.

The bump may contain copper.

The connecting element of the electrically conductive structure may be a mechanically fitted stud bump.

The stud bump may contain copper or gold.

The stud bump may be a stack bump.

A covering layer may be applied on the redistribution layer of the die arrangement whilst leaving free at least the one second electrical connection region.

The die of the die arrangement may have a multiplicity of memory cells.

The die arrangement may have an additional die, the die and the additional die being arranged one above another.

In accordance with a farther embodiment of the invention, a method for producing a die arrangement is provided. The method includes formation of at least one connecting element on a first electrical connection of an at least one first electrical connection region of a die with a multiplicity of electronic circuits that are electrically coupled to one another, at least one first electrical connection region, in which at least one first electrical connection is arranged, and a first passivation layer, which is applied on the upper surface of the die and leaves free at least the first connection, in such a way that the connecting element extends approximately vertically from the electrical connection, and formation of a second passivation layer made of a molding material on the first passivation layer whilst molding in the at least one connecting element, formation of at least one redistribution layer on the surface of the second passivation layer whilst producing an electrical connection to the free end of the at least one connecting element.

Furthermore, the method may include the formation of at least one second electrical connection region with a second electrical connection at the redistribution layer by arranging a covering layer on the top side of the second passivation layer whilst leaving free at least one section at the at least one redistribution layer.

The method may furthermore include the formation of the second passivation layer by means of a molding process.

In accordance with another configuration, the formation of the second passivation layer may be effected by means of a printing process.

The printing process may be for example a vacuum printing encapsulating process (VPES).

In accordance with a further configuration of the method, the at least one connecting element may be formed in a maskless method process.

In accordance with an alternative configuration of the method, the formation of the at least one connecting element on the electrical connection may be effected by mechanical application of a stud bump.

The stud bump may be produced for example by arranging at least two stud bumps one above another.

As an alternative to this, the formation of the at least one connecting element on the electrical connection may be effected by electrodeposition of a bump.

In accordance with one embodiment of the invention, the formation of the bump includes formation of a seed layer, formation of a mask made of a photoresist, electrodeposition of the bump, formation of a seed layer thereon, and removal of the photoresist.

By way of example, a third passivation layer may be arranged prior to the formation of the at least one connecting element on the surface of the first passivation layer whilst leaving free at least the one first electrical connection region.

Furthermore, the formation of the covering layer may be effected by means of screen printing.

What is claimed is:

1. A die arrangement comprising:
a die with a plurality of electronic circuits that are electrically coupled to one another, and at least one first electrical connection region, in which at least one first electrical connection is arranged;
a first passivation layer on the die, wherein the first passivation layer does not extend over the at least one electrical connection;
a second passivation layer comprising a molding material and which is at least partly on the first passivation layer; and
at least one electrically conductive structure comprising a connecting element and a redistribution layer, the at least one electrically conductive structure electrically connecting the at least one first electrical connection region to a second electrical connection region, wherein the second electrical connection region is formed by or at a section of the redistribution layer, the connecting element extending from the at least one first electrical connection region through the first passivation layer and the second passivation layer, and wherein the redistribution layer is coupled to the connecting element, and is at least partly on the second passivation layer.

2. The die arrangement as claimed in claim 1, wherein the second passivation layer is produced by a molding method.

3. The die arrangement as claimed in claim 1, wherein the second passivation layer is produced by a printing process.

4. The die arrangement as claimed in claim 1, wherein the second passivation layer has a thickness of approximately 10 μm to approximately 100 μm.

5. The die arrangement as claimed in claim 4, wherein the second passivation layer has a thickness of approximately 50 μm.

6. The die arrangement as claimed in claim 1, further comprising a third passivation layer between the first passivation layer and the second passivation layer.

7. The die arrangement as claimed in claim 6, wherein the third passivation layer comprises polyimide.

8. The die arrangement as claimed in claim 6, wherein the third passivation layer has a thickness of approximately 1 μm to approximately 10 μm.

9. The die arrangement as claimed in claim 1, wherein the molding material includes an epoxy resin.

10. The die arrangement as claimed in claim 9, further comprising fillers admixed with the epoxy resin.

11. The die arrangement as claimed in claim 1, wherein the molding material contains fillers that influence the coefficient of thermal expansion of the molding material.

12. The die arrangement as claimed in claim 1, wherein the molding material contains fillers that influence the dielectric constant of the molding material.

13. The die arrangement as claimed in claim 1, wherein the molding material has a curing temperature of less than or equal to 180° C.

14. The die arrangement as claimed in claim 1, wherein the connecting element of the at least one electrically conductive structure comprises an electrodeposited bump.

15. The die arrangement as claimed in claim 14, wherein the bump includes copper.

16. The die arrangement as claimed in claim 1, wherein the connecting element of the at least one electrically conductive structure comprises a mechanically fitted stud bump.

17. The die arrangement as claimed in claim 16, wherein the stud bump comprises a material selected from the group consisting essentially of copper, gold, and combinations thereof.

18. The die arrangement as claimed in claim 16, wherein the stud bump is a stack bump.

19. The die arrangement as claimed in claim 1, further comprising a covering layer on the redistribution layer but not extending over the at least one second electrical connection region.

20. The die arrangement as claimed in claim 1, wherein the die includes a plurality of memory cells.

21. The die arrangement as claimed in claim 1, further comprising an additional die, the die and the additional die being arranged one above the other.

22. A method for producing a die arrangement, the method comprising:
providing a die having a major surface and including
a plurality of electronic circuits that are electrically coupled to one another;
at least one first electrical connection region in which at least one first electrical connection is arranged; and
a first passivation layer, which is applied on the upper surface of the die and leaves free at least the at least one first electrical connection;
forming at least one connecting element on the at least one first electrical connection and extending away from the major surface of the die;
forming a second passivation layer made of a molding material on the first passivation layer whilst encapsulating the at least one connecting element; and
forming at least one redistribution layer on the surface of the second passivation layer, but not on a free end of the at least one connecting element.

23. The method as claimed in claim 22, farther comprising forming at least one second electrical connection region with a second electrical connection on the redistribution layer by forming a covering layer on a top side of the second passivation layer whilst leaving free at least one section of the at least one redistribution layer.

24. The method as claimed in claim 22, wherein the second passivation layer is formed by a molding process.

25. The method as claimed in claim 22, wherein the second passivation layer is formed by a printing process.

26. The method as claimed in claim 25, wherein the printing process is a vacuum printing encapsulating process.

27. The method as claimed in claim 22, wherein the at least one connecting element is formed by a maskless process.

28. The method as claimed in claim 27, wherein the at least one connecting element on the at least one first electrical connection is formed by mechanical application of a stud bump.

29. The method as claimed in claim 28, wherein the stud bump is produced by arranging at least two stud bumps one above the other.

30. The method as claimed in claim 22, wherein the at least one connecting element on the at least one first electrical connection is formed by electrodeposition of a bump.

31. The method as claimed in claim 30, wherein the forming of the bump comprises:
forming a seed layer;
forming a mask made of a photoresist;
electrodepositing the bump; and
removing the photoresist.

32. The method as claimed in claim 22, further comprising:
a third passivation layer formed, prior to the forming of the at least one connecting element, on the surface of the first passivation layer, but not on the at least one first electrical connection region.

33. The method as claimed in claim 22, further comprising forming a covering layer partially on the redistribution layer.
